(19) United States
(12) Patent Application Publication
(10) Pub. No.: US 2024/0193760 A1
(43) Pub. Date: Jun. 13, 2024

(54) System for Detecting Defect and Computer-Readable Medium

(71) Applicant: Hitachi High-Tech Corporation, Minato-ku, Tokyo (JP)

(72) Inventor: Hiroshi FUKUDA, Tokyo (JP)

(21) Appl. No.: 18/286,507

(22) PCT Filed: Feb. 25, 2022
(86) PCT No.: PCT/JP2022/007813

§ 371 Date: Oct. 11, 2023

(30) Foreign Application Priority Data
Apr. 27, 2021 (JP) 2021-074653

(51) Int. Cl. G06T 7/00; G06T 7/50

(52) U.S. Cl. CPC G06T 7/001; G06T 7/50; G06T 2207/10061; G06T 2207/20021; G06T 2207/20081; G06T 2207/20084; G06T 2207/30148

(57) ABSTRACT

The purpose of this disclosure is to generate a reference image on the basis of a proper model even for a sample such as a semiconductor device including many patterns and to perform a defect inspection using the reference image. This disclosure proposes one or more computer systems for identifying defects in a received input image. The one or more computer systems include a training device including an autoencoder that has been trained beforehand by inputting multiple images at different positions in a training image. The one or more computer systems divide the input image into multiple input images, input same to the autoencoder, and compare images output from the autoencoder with the input images.

### TECHNICAL FIELD

The present disclosure relates to a method, system, and computer-readable medium for detecting defects, and in particular, a method, a system, and a computer-readable medium for detecting occurrence of minute pattern defects occurring probabilistically very rarely with a high accuracy.

### BACKGROUND ART

There is known a technique for detecting defects included in an image by using an autoencoder. PTL 1 discloses an autoencoder in which three layers of neural networks are supervised and learned by using the same data for an input layer and an output layer, and explains that training is performed by adding noise components to training data in addition to the input layer. There is disclosed, in PTL 2, an original image is divided into grids of small regions, model training is performed by using an autoencoder for each small region, and in the inspection model generated by the model learning, abnormality detection processing is performed for each image data divided as an inspection target to specify an abnormality portion in small region units. In addition, in image classification by using machine training by such as neural networks, performing training by using the plurality of images generated by clipping portions of one image and performing various different processing is generally known as image (or data) augmentation.

### CITATION LIST

### Patent Literature

PTL 1: JP2018-205163A (corresponding US2020/0111217B)

PTL 2: WO2020-031984A

### SUMMARY OF INVENTION

### Technical Problem

PTLs 1 and 2 describe that estimation models are generated in small region units, and abnormality detection is performed in each small region by using the model. Such a technique is effective when the pattern (geometric shape) included in the image is a relatively simple shape.

However, in the case of a sample that has the huge number of edges (the number of sides) per unit region and the huge number of geometric shapes formed by the edges such as a pattern that constitutes a semiconductor device, when the size of the small region is increased, the number of variations of combinations of complicated shapes also becomes enormous, the appropriate model formation is difficult. On the other hand, when the size of the pattern included in the small region is decreased to such an extent that the shape is simple, the number of models becomes enormous, and it is difficult to prepare the model. In addition, it becomes difficult to determine which model to apply.

Hereinafter, similarly to a semiconductor device, even in a sample including many patterns, a method, a system, and a computer-readable medium generating a reference image based on an appropriate model and inspecting defects by using the reference image are described.

### Solution to Problem

In accordance with one aspect of the foregoing objectives, there is provided a system, method, and computer-readable medium for detecting defects on a semiconductor wafer, in which the system is provided with one or more computer systems specifying the defects included in a received input image, the one or more computer systems are provided with a training device including an autoencoder trained in advance by inputting a plurality of images at different locations included in a training image, and one or more computer systems divide the input image, input the divided input images to the autoencoder, and compare an output image output from the autoencoder with the input image.

### Advantageous Effects of Invention

According to the above-described configuration, it is possible to easily detect defects in a complicated circuit pattern with an arbitrary design shape in a short time without by using design data.

### BRIEF DESCRIPTION OF THE DRAWINGS

FIG. 1 is a diagram illustrating a procedure of a defect detection method.

FIG. 2 is a flowchart illustrating the procedure of the defect detection method.

FIG. 3 is a diagram illustrating a concept of a configuration of an autoencoder.

FIG. 4 is a diagram illustrating an example of a frequency distribution of a degree of discrepancy of input and output of the autoencoder.

FIG. 5 is a diagram illustrating an example of an arrangement of inspection sub-images.

FIG. 6 is a diagram illustrating an example of a design pattern of a wiring layer of a typical logic semiconductor integrated circuit.

FIG. 7 is a diagram illustrating an overview of a relationship of circuit design patterns and sub-images.

FIG. 8 is a diagram illustrating an overview of a relationship of a pattern transferred on a wafer and the sub-image;

FIG. 9 is a diagram illustrating a schematic configuration of a defect detection system.

FIG. 10 is a timing chart illustrating a relationship of an imaging process in a scanning electron microscope and an image analysis process in a computer system.

FIG. 11 is a diagram illustrating an example of the scanning electron microscope, which is a type of imaging tool.

FIG. 12 is a diagram illustrating an example of the defect inspection system including the autoencoder.

FIG. 13 is a diagram illustrating an example of a GUI screen that visualizes a defect existence probability distribution.

FIG. 14 is a diagram illustrating a principle of improving the correct answer rate by providing an overlapped region in the sub-image region.

FIG. 15 is a diagram illustrating an inspection process of each of a semiconductor device manufacturing portion and a design portion.

FIG. 16 is a diagram illustrating an example of a GUI screen for setting training conditions.

### DESCRIPTION OF EMBODIMENTS

In defect inspection and defect determination of a wafer attached with a pattern of a semiconductor integrated circuit by using light or an electron beam, an abnormality determination is performed by comparing a pattern image to be inspected with an external normal pattern image. As the normal pattern image, an image having the same pattern created separately (for example, at a different location on the same wafer), a composite image having a plurality of the same patterns (often called a golden image), a design pattern, a simulation image generated from the design pattern, and the like are used.

Unless golden images and design data are prepared for each design pattern, in some cases, it may be difficult to perform appropriate inspection. On the other hand, in recent years, machine training using deep neural networks and the like have been developed, and attempts have been made to detect the defects by using the machine training. However, when this method is applied to inspect random patterns of the semiconductor integrated circuits, the scale of the network becomes unrealistically large, as will be described later. On the other hand, an example where the defect inspection and the defect determination of the wafer having an arbitrary design shape are performed without using the golden images or the design data by embedding the normal pattern information in a neural network of a realistic scale is described.

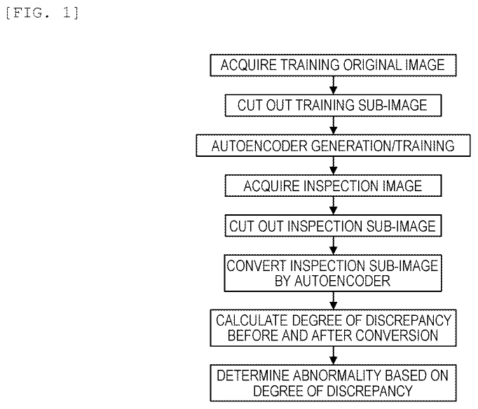

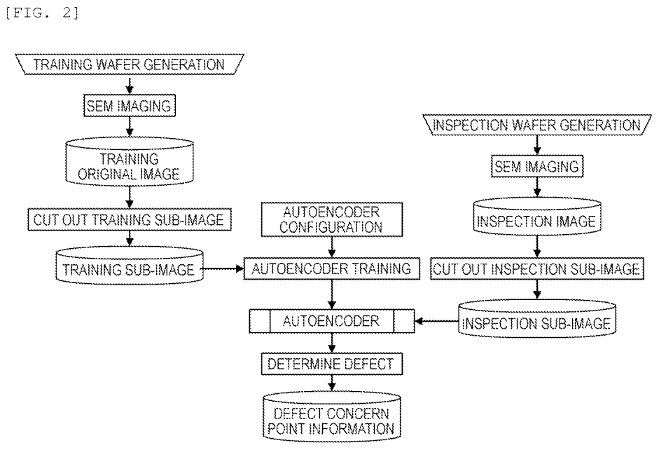

The steps from the image acquisition to the defect detection included in the image will be described below. In this example, mainly a process of inspecting the pattern transferred on the wafer by using a predetermined lithography or etching process from a mask having an arbitrary two-dimensional shape pattern designed according to an established layout design rule will be described. FIG. 1 is a flow chart illustrating a process of generating the autoencoder based on the acquisition of the training original image and performing the defect detection in a series by using the autoencoder, and FIG. 2 is a flow chart illustrating a process of acquiring an image for training the autoencoder and inspection image in parallel and detecting the defect included in the inspection image.

First, an image (training original image) of the pattern designed according to the layout design rule and transferred on the wafer by using the lithography or etching process obtained by capturing a surface of a scanning electron microscope (SEM) is prepared. It is preferable to prepare the plurality of images obtained by capturing different regions on the wafer or the plurality of images obtained by capturing different regions on another wafer having the same design rule and process. Moreover, it is desirable that the image includes a minimum dimension pattern defined by the layout design rule and is acquired for a pattern created under the optimum conditions of the lithography or etching process.

Next, a plurality of training sub-images are clipped at different locations in the training original image. When the plurality of training original images are prepared, the plurality of training sub-images are clipped from each of them. Herein, it is desirable that the angle of view of the training sub-image (for example, the length of one side of the sub-image) may be allowed to set the resolution of the lithography or etching process or the minimum dimension of the layout design rule set to be about F to 4F as F.

Next, one autoencoder is generated by using the plurality of clipped training sub-images as labeled training data. In the embodiment described below, one autoencoder is generated from the plurality of sub-images clipped from different locations of the sample (wafer). This means, instead of generating the autoencoder for each of the plurality of sub-images at different locations, generating one autoencoder by using the sub-images at different locations, and thus this does not mean that the number of autoencoders finally generated is limited to one. For example, the semiconductor devices including the plurality of types of circuits described later may have different circuit performances, and it may be desirable to generate the autoencoder in each circuit. In such a case, in each circuit, the autoencoder of each circuit is generated by using the plurality of sub-images at different locations. In addition, the plurality of autoencoders may be generated according to optical conditions of the SEM, manufacturing conditions of the semiconductor device, and the like.

The sub-images are small region images clipped from a plurality of different shapes or a plurality different locations, and one autoencoder is generated based on the input of these images. It is desirable that a small region image includes a background, a pattern and an edge of a semiconductor device, and the number of patterns or backgrounds included is 1 and it is desirable that both the training image and the input image are sample images generated under the same process conditions, in the same layers, or the like.

In this example, a process of generating one autoencoder by using all the training sub-images included in all captured images as labeled training data after the plurality of captured images are prepared will be described. The set of all training sub-images may be divided into the labeled training data set and the test data set, and the autoencoder may be trained by using the image data of the labeled training data set while verifying the accuracy with the data of the test data set.

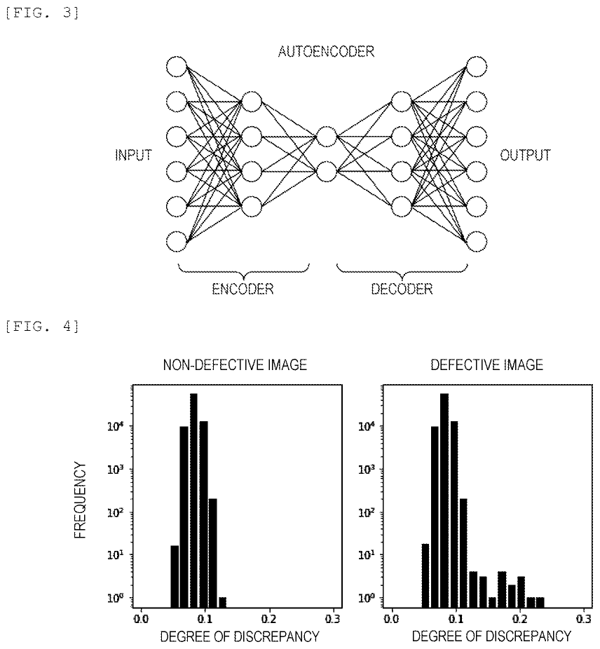

The autoencoder uses normal data as the labeled training data, and a sandglass type neural network illustrated in FIG. 3 is trained. That is, the network is trained, so that when the normal data is input, the input data itself is output. Generally, by using a sandglass type neural network, the amount of information is suppressed to a level necessary for reproducing the normal data as the normal data in the constricted portion of the network. For this reason, when data other than the normal data is input, the data cannot be reproduced correctly. Therefore, it is known that determination of normality or abnormality can be performed by taking the difference of the input and the output.

The autoencoder is configured with an encoder (compressor) and a decoder (demodulator), the encoder compresses the input data into an intermediate layer called a hidden layer vector, and the decoder generates the output data from the hidden layer vector, so that the output data is as close as possible to the original input data. Since the dimension of the hidden layer vector is smaller than the dimension of the input vector, the information of the input data can be considered to be a compressed form. When applied to anomaly detection, the autoencoder is trained by using the normal data as the labeled training data. At this time, although the autoencoder outputs output data as close as possible to the normal data when the normal data are inputted, when data having low appearance frequency are inputted in other data or the labeled training data, it is known that correctly restoring the data is difficult. Therefore, there is known a method of determining the presence and the absence of the abnormality included in the input data by viewing whether or not both match within a certain allowable range.

As the configuration of the autoencoder, a fully-connected multi-perceptron, a feedforward neural network (FNN), a convolutional neural network (CNN), or the like can be used. In the autoencoder, the generally known training methods, such as the number of layers, the number of neurons in each layer or the number of CNN filters, the network configuration of an activation function or the like, a loss function, an optimization method, a mini-batch size, the number of epochs, can be variously used.

By using the characteristics of the autoencoder, the inventor performs an appropriate method, a system, and a non-transitory computer-readable medium for the defect inspection of the semiconductor devices. As a result, the inventors found that, although the shape of the semiconductor device included in the image acquired by the electron microscope or the like is complicated in a wide region, the shape is simple in a narrow region and reduces an image region to the extent that can be considered to be a simple shape, if the narrow region image is input to the autoencoder, it is considered that the defect inspection based on comparison image generation with a high accuracy becomes possible.

For example, a pattern edge included in a certain narrow image region, the intersection (x1, y1, x2, y2) of the frame of the narrow image region, and a curvature r of the boundary (edge) of the inside of the pattern and the background portion are expressed in four bits in principle, and there are about 20 binary neurons, so that the training facilitates.

In addition, as a feature of the semiconductor device that is becoming increasingly miniaturized, the region that can be an inspection target can be extremely large with respect to the size (for example, line width) of the pattern that requires the inspection. As a specific example, when a semiconductor wafer with a diameter of 300 mm is considered to be an island with a diameter of 30 km, a pattern that can be an inspection target corresponds to one branch of a tree. That is, for example, when performing a full-surface inspection, an image capable of recognizing one branch of a tree needs to be imaged throughout the island. Furthermore, in the case of comparison inspection, it is necessary to prepare a reference image that is a comparison target of the inspection image according to the inspection image. A technique that enables such the huge number of images to be acquired with high efficiency is desired.

In this specification, in the image mainly obtained by capturing the semiconductor device, as described above, a method, a system and a non-temporary computer-readable medium for performing defect inspection by dividing the image into narrow regions which can be considered to be a simple shape, inputting the divided image to the autoencoder, and comparing the input image with the output image of the autoencoder are described.

Next, the pattern to be inspected, which is designed according to the layout design rule and transferred on the wafer by using the lithography or etching process, is imaged by an SEM to obtain an inspection image (inspection original image). The plurality of inspection sub-images are clipped from the inspection original image with the same angle of view as the training sub-image and are input to the autoencoder, and the defects are detected from the difference obtained output image (first image) and the input inspection sub-image (second image). As a detection method, for example, for each of the plurality of inspection sub-images, the degree of discrepancy of the input and the output is calculated, a histogram as illustrated in FIG. 4 is created for all the sub-images, and the sub-image exceeding a certain threshold value having the value is output as an image with a high possibility that the defects exist. As the degree of discrepancy, for example, a value obtained by summing the squares of the differences in the illuminance values of corresponding pixels in the input and output images for all pixels can be used. Alternatively, another method of obtaining the difference of the input and the output based on the comparison of the input and the output may be used.

It is noted that, when any deviation from normality occurs in the inspection image, the shape of the histogram indicating the frequency for each degree of difference changes. For example, even in a case where the sub-images exceeding the above-described threshold value are not detected in a specific image to be inspected, for example, when the tail of the histogram extends or the like and an extrapolated value of the frequency of appearance in the vicinity of the degree-of-discrepancy increases, it is expected that the defects will be detected by increasing the inspection image in the vicinity of the inspection point. In addition, even when the defect does not occur, the shape of the histogram is very sensitive to the changes in the process state, and thus by detecting the abnormality and taking countermeasures before the occurrence of the defect, problems of the occurrence of the defect and the like can be prevented in advance. Therefore, the shape change itself can be used as an index of the normality of the process. As an index of the shape change, numerical values such as a mean value, a standard deviation, a degree of distortion, a kurtosis, and a higher-order moment of a histogram distribution may be used.

The computer system is configured to display, on a display device, the histogram having a frequency for each degree of discrepancy (difference information) extracted from the plurality of sub-images as exemplified in FIG. 4. Additionally, the computer system may be configured to evaluate the shape of the histogram by using the index. In order to evaluate changes in the process state, it is possible to monitor changes over time in the process conditions by storing past images of the semiconductor wafers manufactured under the same manufacturing conditions, the histogram extracted from the image, and at least one of the shape data as reference data (first data) in a predetermined storage medium and comparing the reference data with a newly extracted histogram, shape data, or the like (second data).

In order to evaluate the change over time, for example, the change over time of the degree of distortion (index value of shape change) with respect to the original histogram shape may be graphed and displayed or output as a report. Further, as exemplified in FIG. 4, with the same manufacturing conditions, the plurality of histograms extracted from the semiconductor wafers having different manufacturing timings may be displayed together. Furthermore, an alarm may be issued when the degree of distortion or the like exceeds a predetermined value.

Furthermore, a training device that trains data sets such as information on changes (change in histogram shape over time, or the like) in frequency information for each difference information, causes of abnormalities, an amount of adjustment of a semiconductor manufacturing device, timing of adjustment of the semiconductor manufacturing device, or the like as labeled training data may be prepared, and by inputting the frequency information for each difference information to the training device, the cause of the abnormality or the like may be estimated.

When a process fluctuation becomes noticeable, since it is considered that the locations having a large degree of discrepancy of the input and the output increase, for example, by selectively evaluating the frequency of the specific degree of discrepancy (for example, by determining the threshold value), the process fluctuation may be evaluated.

It is preferable that the plurality of inspection sub-images cover the entire region of the inspection original image. In addition, it is desirable that the plurality of inspection sub-images have overlapped regions in common with the adjacent inspection sub-images. For example, when the inspection sub-image is clipped from the inspection image, as illustrated in FIG. 5, the image is clipped at every half distance of the angle of view of the sub-image in the vertical and horizontal directions. When the defects are detected in the two or more adjacent sub-images, it may be determined that there is possibility that the defects exist with a high probability. A region is set so that the plurality of sub-image regions are straddled in the same place, and when the defects are recognized in the plurality of sub-image regions where some regions are overlapped, and the region may be defined as a region where the defects occur with a high probability.

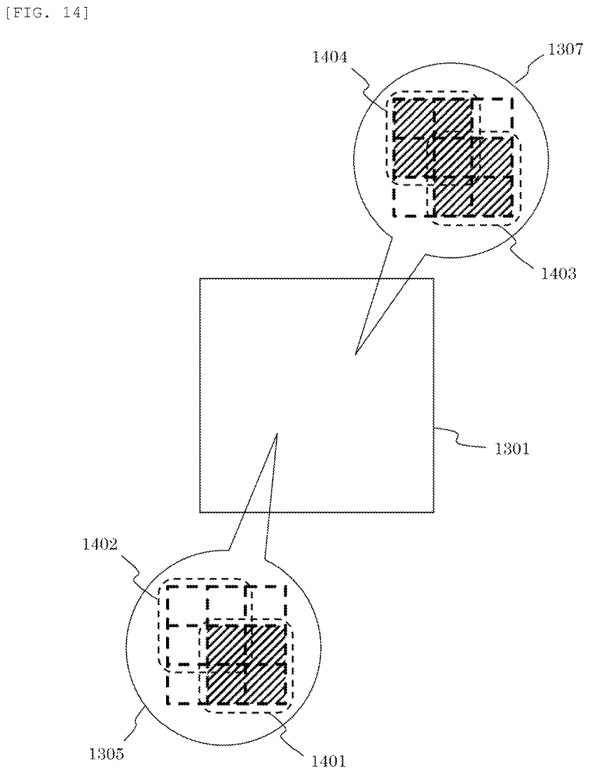

For example, as exemplified in FIG. 13, a GUI may be prepared to display the defect existence probability according to the degree of discrepancy. FIG. 13 illustrates an example where the plurality of sub-image regions 1302 among an image acquisition region 1301 are set while providing, for example, an overlapped region 1303. In a region 1305, for example, the sub-regions 1302 are set at four locations around the overlapped region 1303. The four sub-image regions are set so as to partially overlap in other sub-regions, and the four sub-regions are overlapped in the overlapped region 1303. Areas 1306 and 1307 are similar.

The region 1305 illustrates an example where a sub-region 1308 located in the lower right of the region is extracted as a region having a large degree of discrepancy. In FIG. 13, it is described that the region expressed with slanted lines is extracted as a region having a large degree of discrepancy. In addition, in the region 1306, the sub-image regions of the upper left, upper right, and lower right sub-image regions are extracted, and in the region 1307, the two sub-image regions of the upper left and lower right sub-image regions are extracted as regions having a large degree of discrepancy. Since it is considered that, the larger the number of sub-regions having a degree of discrepancy, the higher the probability of defect occurrence, the identification display according to the number of regions having a large degree of discrepancy per unit region is performed on the map that defines the sample coordinates, so that the defect existence probability can be displayed as a distribution. FIG. 13 illustrates an example of displaying a bar graph 1304 that increases and decreases according to the number of regions with large degrees of discrepancy. It is noted that, in calculating the defect existence probability, for example, weighting according to the size of the degree of discrepancy may be performed. Further, the identification display may be performed according to the statistic amount of the degree of discrepancy of the plurality of sub-regions. Further, the defect existence probability may be obtained according to the number of the overlapped regions per unit region or the density of regions having a large degree of discrepancy.

By plotting the relationship of the sub-image location (for example, center coordinates of the sub-image) and the degree of discrepancy, the distribution of the defect locations in the original image region can be known. The above-described locational distribution is useful for inferring the mechanism of defect generation. Further, by outputting an enlarged SEM image around the location of the sub-image having a large degree of discrepancy, it is possible to directly confirm the abnormality such as a defect shape. In this case, by selecting a bar graph 1304 as exemplified in FIG. 13 on the GUI screen and displaying the image of the region 1305 according to the selection, visual confirmation corresponding to the defect existence probability becomes possible.

Furthermore, when the size of the defect is relatively small compared to the normal pattern, an output F(Id) of the autoencoder when the image Id containing such a defect is input is close to the normal pattern I0 when there is no defect. Therefore, by obtaining the difference of the two, ΔI=Id−F(Id)˜Id−I0, only defects can be extracted from the background pattern. Accordingly, it is possible to estimate and classify the types and shapes of the defects. By allowing the training device including a DNN or the like to be trained by using this difference and pattern shape information as labeled training data, the shape information (or identification information allocated according to the shape of the pattern) extracted from the difference information, the design data, and the SEM images is input to the training device, so that the type and shape of the defect can be estimated.

Next, the mechanism of detecting the defects will be described. The autoencoder trains the sandglass type neural network by using the normal data as the labeled training data, so that input data itself is output when the normal data is input. When the data other than the normal data is input, since it cannot be reproduced correctly, and therefore, by taking the difference of the input and the output, it can be applied to abnormality detection for determining whether normality or abnormality. Therefore, it is considered that the method is applied to the inspection SEM image of the pattern of the semiconductor integrated circuit, and thus the method is applied to the abnormality detection in the pattern. However, the following inspection contents exist.

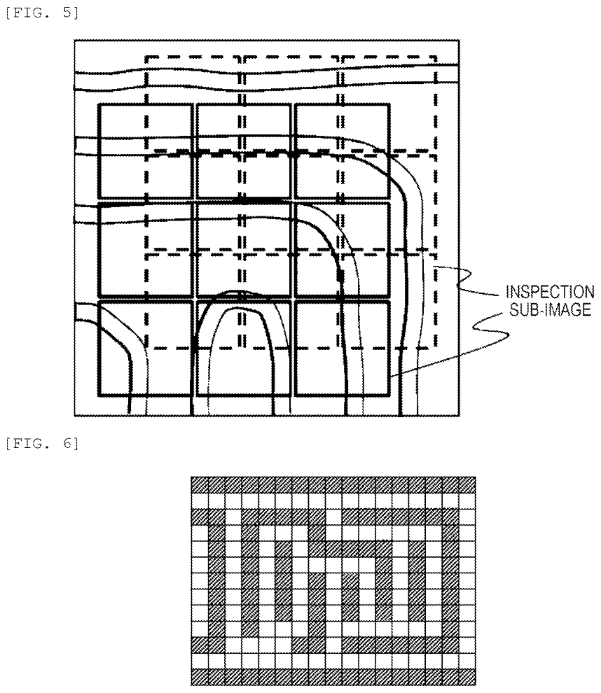

FIG. 6 illustrates an example of a wiring layer pattern of a typical logic semiconductor integrated circuit. Such circuit patterns are generally designed according to a certain layout design rule, and in many cases, the circuit patterns are formed with the pattern regions (lines) with a minimum dimension or more simply extending in the vertical and horizontal directions and the non-pattern regions (intervals (white regions)). The number of variations of such patterns is generally astronomically large. For example, when the allowable minimum pattern design dimension is 20 nm, 25×25=625 minimum dimension pixels exist in a 500 nm square region, which is the imaging region size of a general CD-SEM, and 625-th power of 2 of pattern variations exist. In practice, various other design rule constraints reduce the number of variations below this value, although the number is still astronomically large. In practice, it is extremely difficult to configure and train the autoencoder so as to normally reproduce such an astronomical number of variation patterns. Furthermore, when a defect exists here, the number of variations in combinations of the patterns and the defects further increases according to the place of occurrence and the type of defect, and it is extremely difficult for the network to train this.

In this example, a region with a certain limited angle of view is clipped from an arbitrary layout design pattern. The pattern (object) included in the angle of clipped view changes depending on the locational relationship of the target pattern and the clipped region, and by setting the size of the region to the angle of view of about one to four times the minimum size (for example, 1≤magnification≤4), so that the included pattern is reduced to a relatively simple pattern.

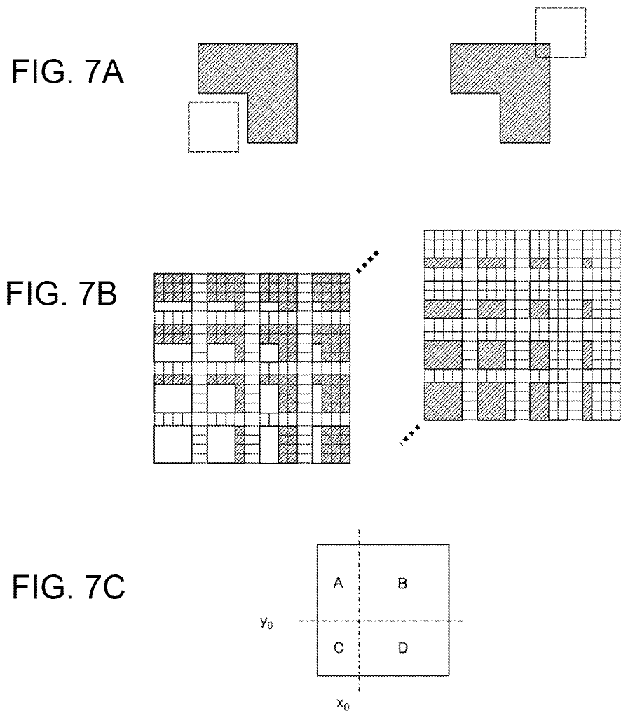

For example, it is assumed that the sub-region is a square with one side having the minimum dimension according to the layout design rules, and the corners of the pattern as illustrated in FIG. 7(a) are clipped. FIG. 7(b) illustrates the aspect of the change of the sub-image when the pattern is clipped by changing the various locations of the sub-region with respect to each corner. For example, when the sub-region is completely outside the pattern as illustrated in the left of FIG. 7(a), the sub-image does not include the pattern region (corresponding to the lower left of FIG. 7(b)). As illustrated in the left part of FIG. 7(a), when the sub-region is at the edge of the pattern corner, the pattern region appears in the lower left of the sub-image (corresponding to the upper right part in FIG. 7(b)).

In this manner, when an arbitrary location of an arbitrary design pattern is clipped by setting the sub-region as a square of which side is the minimum dimension in the layout design rule, at most one pattern region and one non-pattern region are only included. When the pattern is limited to the vertical and horizontal directions, as illustrated in FIG. 7(c), the variations are defined by allocating coordinates x0 of the longitudinal boundary line and coordinates y0 of the lateral boundary line of the pattern region and the non-pattern region to the pattern region or the non-pattern region of each of the four regions A, B, C, and D defined by the two boundaries.

When one side of the sub-region is 20 nm and a design grain size is 1 nm, the number of variations is at most 20×20×2 to the fourth power of 6400, which becomes much smaller than an astronomical number of pattern variations in the 500 nm square region (since the pattern variation within the 500 nm square region is calculated with the design grain size of 20 nm, the difference is further expanded when considering the design grain size of 1 nm).

Next, a case is considered where a sub-region is clipped at an arbitrary location from a pattern after an arbitrary design pattern is transferred on a wafer. In general, a lithographic process can be considered to be low-pass filters for spatial frequencies in a two-dimensional plane.

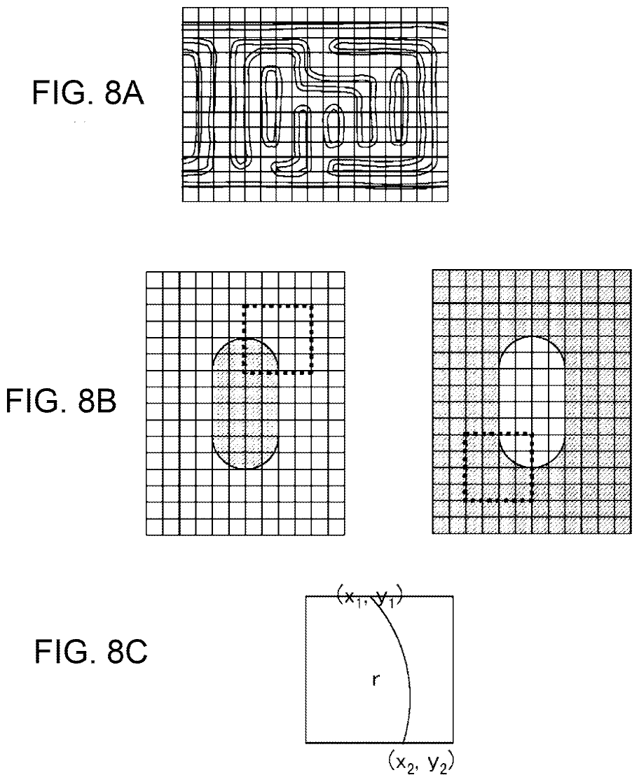

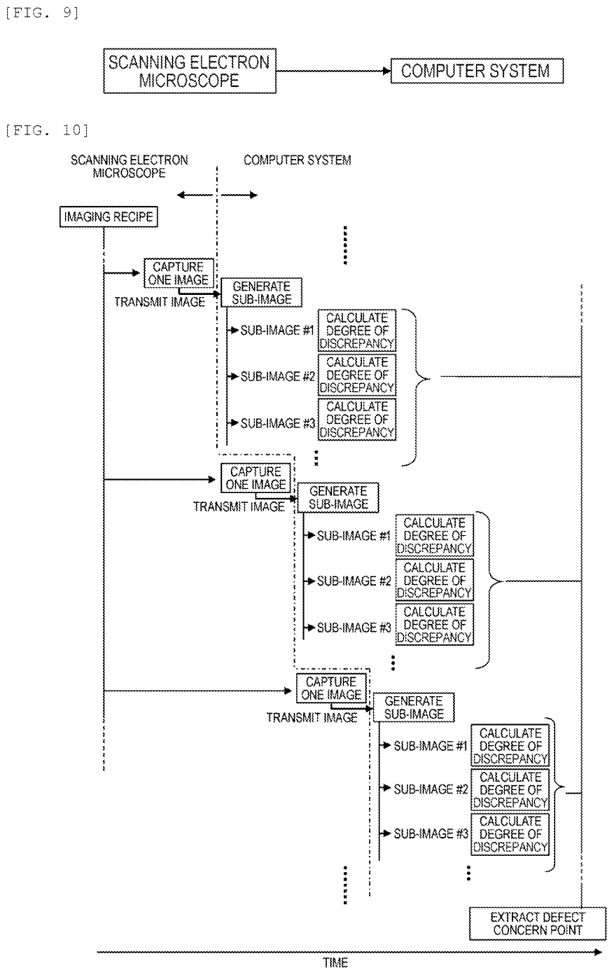

Based on this premise, a pattern with a resolution limit dimension or less is not transferred, and as exemplified in FIG. 8 (a), the corners of the pattern are rounded, and a radius of curvature does not fall below a certain limit. Since the minimum dimension of the layout design rule is set to be larger than the resolution limit, when the pattern is normally transferred, at most one pattern region and non-pattern region are only included in the sub-region, and the boundary thereof is a curve with the radius of curvature which is the limit radius of curvature or more. As illustrated in FIG. 8(c), the number of variations of such pattern is also approximately defined by the intersection coordinates (x1, y1) and (x2, y2) of both ends of the outer periphery of the sub-region and the boundary and the radius of the curvature r and is on the same order as the number of variations of the design pattern in the sub-region. According to the study of the inventor, it is possible to configure a neural network with a scale capable of calculating the autoencoder that reproduces a normal input pattern image as an output while suppressing the number of variations to this level.

On the other hand, when a portion below the resolution limit dimension or less or a portion with the radius of curvature below the limit value or less appears in the transferred pattern, such a portion can be considered to have some type of abnormality. By configuring the autoencoder so as not to correctly reproduce an input image other than a normal transferred image, when the abnormal pattern is input, the difference of the input and the output increases, and thus by detecting the difference, it is possible to detect the possibility that the abnormality has occurred.

In the above description, the size of the sub-image to be clipped is assumed to be a square with one side having the minimum design dimension, but this is an assumption for the simplicity of description and is not actually limited to this. For example, when one side is larger than the minimum design dimension, the number of pattern variations included in one side is larger than the value described above, but the above description holds as long as the configuration and training of the autoencoder are possible. However, it is desirable that the length of one side of the sub-image is 2 to 4 times the minimum dimension of the design pattern or 2 to 4 times or less the resolution limit dimension of the lithography or etching process used for the transferring. A resolution limit dimension W is represented by a wavelength λ of light used in lithography, a numerical aperture NA of an optical system, a proportional constant k1 depending on an illumination method or a resist process, and a spatial frequency magnification amplification factor Me of an etching process.

$$W = Me \cdot k 1 \cdot \frac{λ}{NA} \qquad [ Mathematical Formula 1 ]$$

Me is 1 for the case of etching the pattern formed by lithography as it is, ½ for the case of a so-called self-aligned double patterning) (SADP) or litho-etch-litho-etch (LELE) process, ⅓ for the case of an LELELE process, and 0.25 for the case of a self-aligned quadruple patterning (SAQP) process. Thus, Me is a value determined according to the type and principle of multi-patterning.

In order to appropriately select the size of the sub-region, the appropriate size of the sub-image may be selected by storing Equation 2, for example, in a storage medium of the computer system and inputting necessary information from an input device or the like.

$$SI = M \cdot Me \cdot k 1 \cdot \frac{λ}{N A} \qquad [ Mathematical Formula 2 ]$$

M is a multiple (for example, 2≤multiple≤4) of the minimum dimension of the pattern, as described above. It is noted that all the values are not always necessarily input, for example, when the wavelength of light used for the exposure is fixedly used, the size of the sub-image may be obtained by treating other information as already input information as input. Further, as described above, a size SI (length of one side) of the sub-region may be calculated based on the input of the dimensions of the layout pattern.

In the training of the autoencoder, it is necessary to use various variations of normal patterns as labeled training data. In this description, the variation can be covered by clipping the images of the various transferred patterns including the patterns designed with minimum allowable dimensions at the various different locations. For example, as illustrated in FIG. 8(b), a rectangular pattern with rounded corners is clipped by varying the location of the window indicated by a dotted line, and the training sub-image of the variations as illustrated in FIG. 8(c) can be generated. In addition, patterns clipped at various different angles may be added.

Furthermore, since it is difficult to exactly match the actual transfer pattern with the intended design dimensions, the fluctuations are allowed within the range determined by design. A transfer pattern within the allowable range needs to be determined to be normal. In addition, the edge of an actual transfer pattern has random unevenness called line edge roughness. With respect to this line edge roughness, unevenness within a range determined by design is allowed. The transfer pattern within the allowable range needs to be determined normal. These dimensions and the aspect of unevenness of the edge vary according to the location on the wafer. For this reason, by clipping the various patterns of the same design or the similar designs existing on the same wafers or the different wafers at the various different locations, the variations within these normal ranges can be covered.

Furthermore, when an image is acquired by the SEM or the like, a relative locational relationship of the angle of view and the pattern changes depending on a positioning accuracy of the wafer stage and the like. Therefore, the relative locational relationship of the angle of view of the sub-image acquired from the SEM image and the pattern included therein also changes. The normal pattern needs to be determined to be normal for these various relative locational relationships. Variations within these normal ranges can be covered by clipping different patterns of the same or the similar designs at different locations.

Next, a basic idea for increasing a correct answer rate of the defect detection will be described. In order to increase the correct answer rate, first, it is desirable that the autoencoder is configured and trained, so that the degree of discrepancy with respect to the abnormal patterns is increased as much as possible while the degree of discrepancy of the input and output of the autoencoder with respect to the normal patterns maintains small.

As an extreme example of the above-described configuration, first, when the input and the output are directly connected and the input is output as it is, since both the normal pattern and the abnormal pattern are output as they are, it is impossible to determine both by the difference of the input and output. Next, as a second extreme example, when the number of neurons in the constriction of the sandglass network is set to 1, generally, there is a concern that the variation of the input pattern cannot be represented. In this case, the degree of discrepancy also increases with respect to the normal pattern. Therefore, it is desirable to set the number of neurons in the layer of the constricted portion to the minimum necessary to reproduce the input. Generally, in deep learning including autoencoders, it is difficult to theoretically obtain the optimum network configuration for such individual purposes. Therefore, the configuration of the network including the number of neurons in the constricted layer needs to be set by trial and error.

Next, factors that degrade the correct answer rate will be described. The patterned region or the non-patterned region may exist at the edge of the field of view (FOV) of the sub-image and may be detected as an abnormality without being reproduced by the autoencoder. In this case, the width of the pattern region or the non-pattern region is really abnormally small, or it is difficult to determine whether the end of pattern region having the normal width or the non-pattern region overlaps the sub-region, and in the latter case, it becomes an erroneous detection. This erroneous detection is resolved by considering together the abnormality determination in the sub-images adjacent to the sub-image, preferably adjacent to the overlapping portions.

When the width of the patterned region or the non-patterned region is truly abnormally small, the region will also be detected as abnormal in the adjacent sub-image. On the other hand, when the width of the patterned region or the non-patterned region having a normal width is in the normal range, no abnormality is detected in the adjacent sub-image. Therefore, as illustrated in FIG. 5, the feed pitch of the detection sub-region is set to be smaller than the angle of view of the sub-region, and when the abnormality is simultaneously detected in the adjacent sub-image, it is determined as a true abnormality, and thus the correct answer rate is improved.

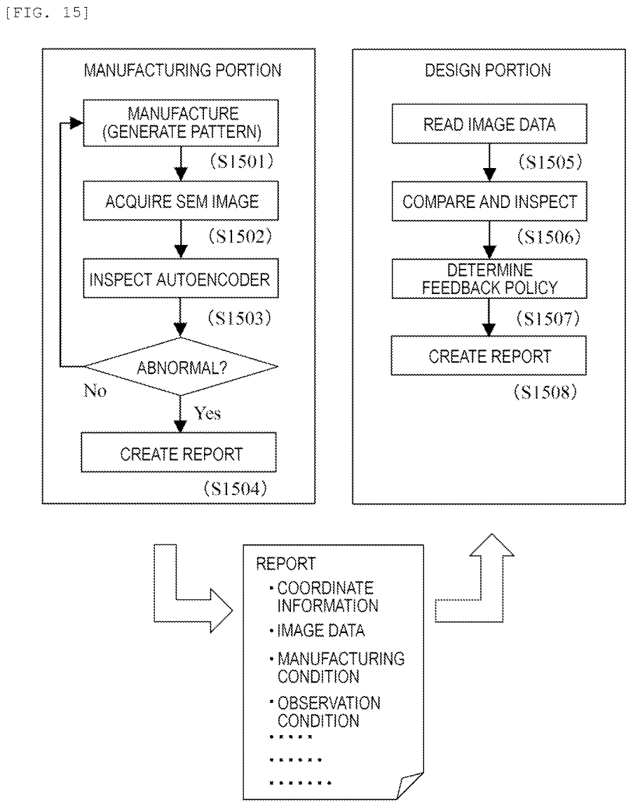

FIG. 14 is a diagram illustrating the principle of improving the correct answer rate by providing an overlapped region in the sub-image region (setting the feed pitch of the sub-image region to be smaller than the angle of view). The example of FIG. 14 exemplifies the case where the feed pitch of the sub-image regions (1401 to 1404) on the image acquisition region 1301 is half that of the sub-image region. FIG. 14 illustrates an example where the abnormality is detected in the sub-image regions 1401, 1403, and 1404 included in regions 1305 and 1307, and the abnormality is not detected in the sub-image region 1402. As described above, since no abnormality is detected in the sub-image region 1402 adjacent to the sub-image region 1401 in which an abnormality has been detected in the region 1305, in comparison with the region 1307, there is a high possibility that it is relatively not abnormal. By including such a determination procedure, an improvement in the correct answer rate of the anomalies and the probability of anomalies can be quantitatively evaluated.

In addition, in the case of the example of FIG. 14, although the four sub-image regions are set for the one overlapped region, the sub-images in which the abnormality is detected centering on the location where the defect exists are considered to be concentrated. Therefore, it is possible to expect the effect of specifying the locations where the defects are considered to be located by evaluating the frequency (for example, the number of abnormal images per unit region) of the sub-images in which the abnormality is detected for each location.

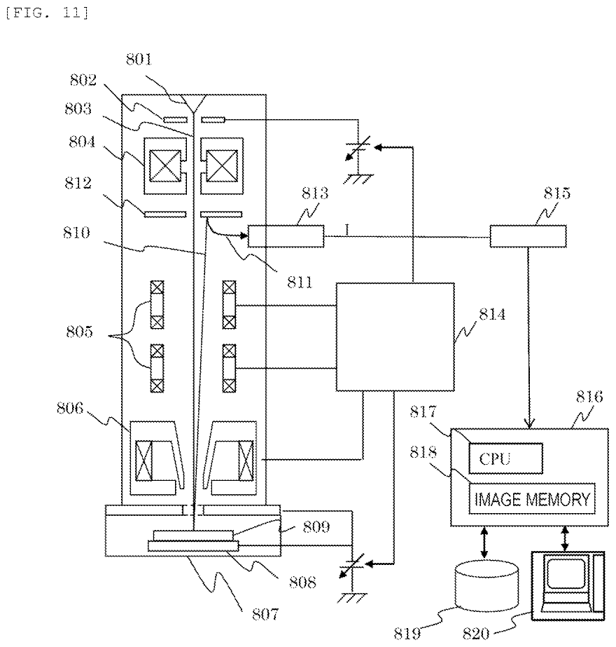

Next, the inspection system including the autoencoder will be described with reference to FIG. 9. The system is configured with a scanning electron microscope and one or more computer systems for storing image data output from the scanning electron microscope and processing the data. The computer system is configured to read a program stored in a predetermined computer-readable medium and execute a defect detection process as described later. The computer system is configured to communicate with the scanning electron microscope. The computer system may be remote from the scanning electron microscope in connection to the scanning electron microscope by one or more transmission media or may be a module of the scanning electron microscope.

First, the scanning electron microscope images the wafer pattern created under the optimum conditions and transfers the image data to the computer system. The computer system stores the images as the training images and generates the autoencoder from the training images. Next, the scanning electron microscope images an inspection-target wafer pattern and transfers the image data to a computer system. The computer system stores the image as the inspection image data, and detects the defects from the inspection image data by using the autoencoder. Further, the computer system outputs a signal for displaying at least one of the inspection results, the inspection conditions, the electron microscope images, or the like on the display device. The display device displays necessary information based on the signal.

With respect to the imaging of the inspection image, the sub-image generation, and the degree of discrepancy calculation, a pipeline method processing and parallel computation may be combined as illustrated in FIG. 10. That is, the scanning electron microscope captures an image of a designated location on an inspection wafer according to an imaging recipe. Immediately after each location is captured, each image is transferred to the computer system, and the image of the next designated location is captured according to the imaging recipe. The computer system generates the plurality of sub-images from the sequentially transferred images and calculates the degree of discrepancy for each sub-image. Herein, the degree of discrepancy calculation for the plurality of sub-images may be processed in parallel.

In the scanning electron microscope exemplified in FIG. 11, an electron beam 803 is extracted from an electron source 801 by an extraction electrode 802 and accelerated by an acceleration electrode (not illustrated). The accelerated electron beam 803 is condensed by a condenser lens 804 which is one form of a focusing lens, and then deflected by a scanning deflector 805. Accordingly, the electron beam 803 scans a sample 809 one-dimensionally or two-dimensionally. The electron beam 803 incident on the sample 809 is decelerated by a decelerating electric field formed by applying a negative voltage to an electrode incorporated in a sample stage 808 and focused by the lens action of an objective lens 806 to irradiate the surface of the sample 809.

Vacuum is maintained inside a sample chamber 807.

Electrons 810 (secondary electrons, backscattered electrons, or the like) are emitted from the irradiation portion on the sample 809. The emitted electrons 810 are accelerated toward the electron source 801 by the acceleration action based on a negative voltage applied to the electrodes provided to the sample stage 808. The accelerated electrons 810 collide with conversion electrodes 812 to generate secondary electrons 811. The secondary electrons 811 emitted from the conversion electrode 812 are captured by a detector 813, and the output I of the detector 813 changes depending on the amount of captured secondary electrons. As the output I changes, the illuminance of the display device changes. For example, when forming a two-dimensional image, the deflection signal to the scanning deflector 805 and the image of the scanning region are formed in synchronization with the output I of the detector 813.

It is noted that the SEM exemplified in FIG. 811 illustrates an example where the electrons 810 emitted from the sample 809 are once converted into the secondary electrons 811 at the conversion electrode 812 and detected, but of course, the configuration is not limited to such a configuration, and for example, a configuration in which an electron double image tube or a detection surface of the detector is disposed on the trajectory of accelerated electrons may be adopted. A controller 814 supplies necessary control signals to each optical element of the SEM according to an operation program for controlling the SEM called an imaging recipe.

Next, the signal detected by the detector 813 is converted into a digital signal by an A/D converter 815 and transmitted to an image processing unit 816. The image processing unit 816 generates an integrated image by integrating signals obtained by the plurality of scans on a frame-by-frame basis, if necessary. Herein, an image obtained by scanning the scanning region once is called one frame of an image. For example, when eight frames of images are integrated, the integrated image is generated by adding and averaging signals obtained by eight times of two-dimensional scanning on a pixel-by-pixel basis. It is also possible to scan the same scanning region multiple times and generate and store a plurality of one-frame images for each scan. The generated image is transmitted to an external data processing computer at a high speed by an image transmission device. As described above, image transmission may be performed in parallel with imaging in a pipeline system.

Furthermore, the whole control having a storage medium 819 for storing measurement values of each pattern and illuminance values of each pixel is performed by a workstation 820, and the operation of the necessary device, confirmation of detection results, or the like can be realized through a graphical user interface (hereinafter referred to as GUI). In addition, an image memory is configured to store the output signal (the signal proportional to the amount of electrons emitted from the sample) of the detector at the address (x, y) in a corresponding memory in synchronization with the scanning signal supplied to the scanning deflector 805. It is noted that the image processing unit 816 functions as an arithmetic processing unit that generates a line profile from the illuminance values stored in the memory, as needed, specifies edge locations by using a threshold value method or the like, and measures dimensions of edges.

FIG. 16 illustrates a GUI screen for setting training conditions (training conditions). The GUI screen illustrated in FIG. 16 is provided with a setting column 1601 for setting a file name or a folder name in which training images and metadata attached to each image are placed. Based on the settings herein, the computer system reads the image data and the metadata from a built-in or external storage medium and displays the image data and the metadata in the attached information display column 1606 and the SEM image display column 1607, respectively. Furthermore, on the GUI screen exemplified in FIG. 16, a setting column 1602 for setting the dimension Lsub (angle of view) of the sub-image is provided. It is noted that a minimum size F of the pattern included in the image and a coefficient n by using the minimum size F as a unit may be input from the setting column 1602. In this case, the dimensions of the sub-image are calculated based on a predetermined formula (sub-image size=F×n (1≤n≤4)). In addition, an input column may be used in which at least one of the number of pixels Npxl (the number of pixels in at least one of the vertical and horizontal directions or the total number of pixels) of the sub-image can be input. One or more of the plurality of parameters related to the dimensions, the minimum dimensions of the pattern, the dimensions of the sub-image of the number of pixels, and the like may be selectable.

The GUI screen exemplified in FIG. 16 further includes a setting column 1603 for setting the pitch Ps of the sub-images. In the setting column 1603, the same parameters as those in the setting column may be input, or an exclusion region width Wexcl around the sub-images (interval width of the sub-images not acquired as the sub-images) may be input. In addition, the plurality of parameters may be input together. Further, on the GUI screen exemplified in FIG. 16, a setting column 1604 is provided for setting the number of sub-images to be selected from the sub-images clipped under the conditions set in the setting columns 1601 to 1603 and the like. Herein, although the number of sub-images to be provided for the training is set, when the maximum number of samples (sub-images) that can be set for the setting value (=((Lo−2Wexcl−Lsub)/Ps)², Lo (the length of one side of the original image) is exceeded, the computer system notifies the fact or sets the maximum number of samples that can be set. It is noted that it is also possible to take training time into account and not to use all the data.

Furthermore, on the GUI screen exemplified in FIG. 16, a setting column 1605 for setting the type of neural network is provided. The neural networks that can be set in the setting column 1605 include, for example, an autoencoder (AE), a convolutional autoencoder (CAE), a variational autoEncoder (VAE), a convolutional variational autoencoder (CVAE), and the like. These modules are built into or stored in the computer system.

In addition, a parameter for a neural network configuration such as a setting column capable of setting optimization parameters such as Latent dimension, Encoding dimension, the number of stages, the number of neurons (or filters), the activation function, the mini-batch size, the number of epochs, the loss function, the optimization method, the ratio of the number of pieces of training data and verification data, or the like may be provided. Further, a setting column may be provided for setting the model configuration and a network weighting coefficient storage file name or a folder name.

Furthermore, it is desirable to provide a display column on the GUI screen so that the training result can be determined visually. Specifically, it is a histogram of the degree of discrepancy and an in-plane distribution of the degree of discrepancy of each image for training. The pieces of information may be displayed by selecting tags 1608 and 1609, for example. Furthermore, as supplementary information, the model configuration and the weighting coefficient storage file or the folder name of the network may be displayed together.

In addition, although FIG. 16 has been described as a GUI for setting the training conditions, in the GUI screen for setting the inspection conditions, it is desirable that a folder on which inspection target images and metadata attached to each image are placed, a sampling pitch Ps of the sub-image, the exclusion region width Wexcl around the image, a model structure used for the inspection, a file name of a weight factor of the network, a threshold value of the degree of discrepancy used for the defect determination, a file name of storing the inspection result data, a folder Name, and the like can be set.

By enabling setting by using the GUI as described above, it becomes possible to perform the model generation and the defect inspection under the appropriate training conditions and inspection conditions.

Hereinafter, Application Example of the defect detection method by using the autoencoder is illustrated below.

### Application Example 1

A wiring layer pattern for a logic LSI (semiconductor integrated circuit) including logic circuits and SRAMs is exposed on a wafer having a predetermined base layer coated with an EUV resist by using an exposure device with NA of 0.33 and a resist processing device by using EUV light with a wavelength of 13.5 nm to form the resist pattern. Predetermined optimum conditions are used for an exposure amount, focus, resist processing conditions, and the like obtained in advance. An training original image is imaged by a logic circuit unit and an SRAM unit at a plurality of locations within a wafer surface avoiding a wafer peripheral portion by using the SEM as exemplified in FIG. 11, transmitted to a data processing computer, and stored.

It is assumed that the training original image has a pixel size of 1 nm and an FOV of 2048 nm (length of one side). Next, 39601 training sub-images of 50 nm-square are clipped in each of all the acquired training original images at a feed pitch of 10 nm in the vertical and horizontal directions.

Next, the following autoencoder is configured with the data processing computer. The input is a vector with a length of 2500, which is an one-dimensional version of the two-dimensional image data in which the illuminance value (gray level) of the image pixel is the value of each element, and in the network configuration of the autoencoder, from the input side, the number of neurons is all coupled layers of 256, 64, 12, 64, and 256, the final output is a vector, which is the same as the input, with a length of 2500. In addition, ReLU is used as the activation function for each layer except for a final layer. 80% of the training sub-images are selected at random as the labeled training data, and training is performed. Mean square error is used as a loss function, and RMSProp is used as an optimization algorithm. It is noted that the pixel size, the original image size, the sub-image size, the network configuration, the training method, and the like are not limited to those illustrated above.

Next, the inspection original image of the pattern including the minimum dimension is obtained at the peripheral portion of the wafer. In addition, an inspection focus exposure matrix (FEM) wafer is created by using the same materials and process device, and the inspection original images of the patterns including the minimum dimensions formed under the various exposure and focus conditions deviated from the predetermined optimal conditions are acquired.

The FEM wafer is an exposure transfer of chips on the wafer under various conditions of the focus and the exposure amount. In each of these inspection original images, 9801 inspection sub-images of 50 nm square are clipped at a feed pitch of 20 nm in the vertical and horizontal directions. Each of these inspection sub-images is input into the autoencoder, and the output is calculated. The degrees of discrepancy of the input vector and the output vector are calculated by summing the squares of the deviations of the corresponding elements of the input vector and the output vector. A histogram of the degrees of discrepancy of all the inspection sub-images is created, and the inspection sub-images of which degree of discrepancy is the threshold value or more are extracted.

Furthermore, among the extracted inspection sub-images, adjacent ones are extracted, and the average coordinates of the centers of the sub-images adjacent to each other are stored and output as the coordinates of a defect concern point. In addition, the image centered at the above-described location (including the above-described adjacent sub-images with the difference exceeding the threshold value) is output. As a result of confirming the image of the defect concern point, a so-called stochastic defect is recognized. The occurrence frequency of the defect concern point is increased at the periphery of the wafer by deviating exposure and focus conditions from the optimum point. Accordingly, an effective area range and exposure and focus conditions for obtaining a predetermined yield on the wafer are clarified.

### Application Example 2

In this embodiment, instead of the SEM used for imaging the pattern in the first embodiment, an SEM capable of having relatively large beam deflection (scanning) is used as an imaging device. The pixel size of the training original image and the inspection original image is set to 2 nm, and the FOV size is set to 4096 nm. From each of the training original images, 163,216 training sub-images with 48 nm squares are clipped at a feed pitch of 10 nm in the vertical and horizontal directions. Similarly, 113,569 training sub-images with 48 nm squares are clipped at a feed pitch of 12 nm in the vertical and horizontal directions. With respect to the inspection sub-images, 40,804 training sub-images with 48 nm squares are clipped from each image at a feed pitch of 20 nm in the vertical and horizontal directions.

In this embodiment, a convolutional neural network (CNN) is used for the autoencoder. The input is two-dimensional image data (30×30 two-dimensional array) with each pixel illuminance value (gray level) as an element, in the network configuration of the autoencoder, the number of convolution filters is set to nine layers from an input side: 12, 12, 12, 12, 12, 12, 12 and 1, and the size of the convolution filter is set to 3×3. A 3×3 max pooling layer in the rear stage including each convolution first half two layers, a 3×3 max pooling layer in the rear stage including each subsequent convolution two layers, a 2×2 up sampling layer in the rear stage including each second half convolution two layers, and a 3×3 up sampling layer in the rear stage including each subsequent convolution two layers are provided.

In addition, an activation function ReLU is provided after the max pooling layer and the upsampling layer. The activation function of the final layer is set as a sigmoid function, binary_crossentropy is set as a loss function, and the network is trained by using Adam as an optimization algorithm.

Next, the pattern transferred on the wafer is inspected by using the same lithography or etching process as that for the training wafer with another mask designed according to the same layout rule as the wafer used for the training. According to the present embodiment, the same defect inspection as in the first Application Example can be performed for a wide range of patterns in a short period of time. The imaging conditions, the image cropping method, the autoencoder network configuration, the training method, and the like in this embodiment are not limited to those described above. For example, a variational autoencoder, a convolutional variational autoencoder, or the like may be used.

In the inspection as described in the first Application Example and the second Application Example, the design data unlike the Die to data base inspection method is not required. However, in order to investigate the influence of the detected pattern abnormality on the performance deterioration, malfunction, or the like of the integrated circuit, it is desirable to determine the pattern abnormality by comparing the pattern abnormality with the design data. The determination work is usually performed in a circuit design portion, a product yield management portion, or the like, not in the manufacturing process of the integrated circuit where the inspection by this method is performed. Therefore, the in-chip coordinates and the image data of the abnormal pattern extracted in the manufacturing process by this method may be transmitted to the circuit design portion, the yield management portion, or the like holding the design data. The circuit design portion, the yield management portion, or the like determines whether the detected abnormality is acceptable in terms of circuit performance and function based on the above-described coordinates and images, and when the detected abnormality is not acceptable, necessary countermeasures are taken. Therefore, in this method, the yield management based on design data can be performed without holding the design data in the manufacturing process.

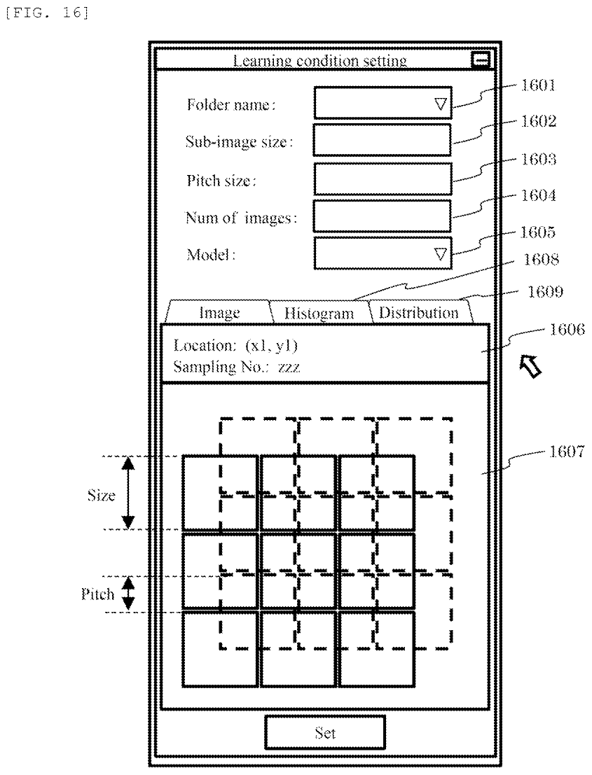

As exemplified in FIG. 15, generally, a pattern of a semiconductor wafer is generated by lithography or the like by using a photomask created based on design data designed by a design portion (step 1501). In the manufacturing portion, the resist pattern and the like are evaluated by a measurement apparatus and an inspection device of such as a CD-SEM to determine whether the manufacturing is being performed under appropriate conditions. In Application Example as described above, the SEM image is acquired for the semiconductor device pattern manufactured in the manufacturing portion (step 1502), and the inspection using the autoencoder is performed by clipping the sub-image (step 1503).

In the manufacturing portion, the inspection using the autoencoder is performed, and the image data obtained by capturing the pattern that can be considered to be abnormal is selectively transmitted to the design portion and the yield management portion. In the design portion, the image data transmitted from the manufacturing portion is read (step 1505), the semiconductor device is designed at the time of designing, and the comparison inspection with the held design data is executed (step 1506). It is noted that, for comparison inspection, the design data is diagrammed as layout data. In addition, the pattern edges included in the image data are thinned (contoured).

The design portion determines whether to consider the design change based on the above-described comparison inspection or to continue manufacturing without the design change by reviewing the manufacturing conditions or the like.

The computer system of the manufacturing portion side executes inspection by the autoencoder and creates the report to the design portion based on the inspection results (step 1504). The report to the design portion includes, for example, the coordinate information of the location where the abnormality is found and the SEM image, and may also include the manufacturing conditions, SEM apparatus conditions (observation conditions), and the like. Further, the report may include information such as the frequency distribution of the degree of discrepancy as exemplified in FIG. 4 and the probability of defect occurrence in the surroundings.

On the other hand, the computer system of the design portion side executes comparison inspection and creation of the report based on the inspection results (step 1508). The report may include the results of the comparison inspection, and may also include the defect types specified as a result of the comparison inspection, the inspection conditions, and the like. Furthermore, the computer system of the design portion side may include a training device such as a DNN trained by a data set of comparison inspection results and past feedback history (whether the design is changed or the manufacturing conditions are adjusted, or the like). By inputting the comparison inspection results (difference information of the corresponding locations of outline data and layout data, or the like) to the training device, correction of the design data, a policy of the correction, policy of correction of the manufacturing conditions, and the like are output (step 1507). It is noted that the training device can be replaced with a database that stores the relationship of the comparison test results and the feedback policy.

### Application Example 3

A word line layer mask of a DRAM is exposed on a wafer having a predetermined base layer coated with an EUV resist by an exposure device with an NA of 0.33 and a resist processing device using EUV light with a wavelength of 13.5 nm to form the resist pattern. Predetermined optimum conditions obtained in advance are used for an exposure amount, focus, resist processing conditions, and the like. A training original image is imaged by a memory cell portion by using a wide FOV compatible SEM in the same manner as in Application Example 2 at a plurality of locations within a wafer surface avoiding a wafer peripheral portion, transmitted to a data processing computer, and stored. After that, the training sub-images are generated in the same manner as in Application Example 2, and the autoencoder is created by using these sub-images.

Next, in the word line exposure process of a mass production line of the DRAM, the wafer is extracted at a predetermined frequency, inspection images are acquired at the plurality of predetermined locations within the wafer surface, and the inspection sub-image having the same size as the training sub-image is generated. The inspection sub-image is input to the autoencoder, and the degree of discrepancy from the output is calculated. When the locations with high defect possibilities are extracted from the degree of discrepancy and the distribution within the inspection image is obtained, two cases of the defects that appear randomly and the defects that are concentrated in a linear distribution are found.

As a result of analyzing the enlarged SEM image of the above-described location, it is clarified that the former is a stochastic defect caused by the fluctuations in the exposure conditions of the EUV resist while the latter is caused by foreign matters during the exposure process, and thus the occurrence of defects is reduced by taking countermeasures for each.

In this Application Example, although the training pattern and the inspection target pattern are fixed to the specific process layer pattern of the specific LSI, even in this case, the autoencoder determining the locational deviation of the inspection image, dimensional fluctuation within the allowable range, and line edge roughness (LER) as normal can be generated by performing training by inputting the plurality of images acquired at the different locations.

### Application Example 4

A wafer created by the same method as when preparing the wafer for acquiring the training original image in Application Example 1 is inspected by using an optical defect inspection device for patterned wafers and is output to a location where there is defect possibility.

The pattern observation image is captured by using a review SEM centering on the output in-plane location of the wafer, and defects are detected by using the autoencoder created in Application Example 1. The difference image of the input image and the output image of the autoencoder is output for the sub-image of the location where the defect is detected. As a result, in the distribution of the difference within the angle of view of the original image, local (dot-shaped) protrusions or recesses, linear protrusions or recesses straddling the patterns, linear protrusions or recesses along the pattern edge, unevenness along the pattern edge, fine unevenness spreading throughout the image, smooth unevenness spreading throughout the image, and the like are classified. These sequentially suggest, for example, microforeign substances, a bridge between the patterns, a separation of the pattern, a shift of the pattern edges, roughness of the pattern edges, a noise of images, and a shift of image illuminance.

### Application Example 5

In a wafer created by the same method as when preparing the wafer for acquiring the training original image in Application Example 3, a DRAM memory cell region on the whole surface thereof is inspected by using an optical defect inspection device for patterned wafers, and the wafer in-plane distribution of a haze level is measured. The defect inspection is performed by the method illustrated in Application Example 2 for regions where the haze level is higher than the predetermined threshold value.

### Application Example 6

With respect to a wafer created by the same method as when preparing a wafer for training original image acquisition in Application Example 1, a risk region of the defect occurrence is estimated in advance from pattern design information, pattern simulation based on the above information, output information such as a focus MAP from a process device such as an exposure device, output of various measuring devices such as wafer shapes, and the like. The defect inspection is performed by the method illustrated in Application Example 2 for regions where the estimated defect occurrence risk is high.

### Application Example 7

In Application Example 1 to Application Example 6, defects are determined and the types thereof are classified by using a so-called auto defect classification (ADC) from a pattern image including defect concern point coordinates extracted by defect inspection. As the types of defects, a bridge between pattern lines, breakage of the pattern lines, disappearance of isolated patterns, excess of allowable value of LER, local undulations of the pattern lines, other pattern dimensional shape fluctuations, various foreign matter defects, and the like are determined. According to an inspection method by using the autoencoder, the pattern abnormalities can be extracted at a high speed without by using a golden image, design information, or the like. By combining this with other methods such as the ADC, it is possible to classify and analyze the extracted defects, analyze the cause of defect generation, and take countermeasures.

For example, the efficiency of inspection can be improved by selectively performing the comparison inspection and the ADC on the SEM image of the portion where an abnormality is found by the autoencoder. Further, by performing both the normal inspection and the autoencoder inspection, it is possible to further improve a detection accuracy of the defect.

### Application Example 8

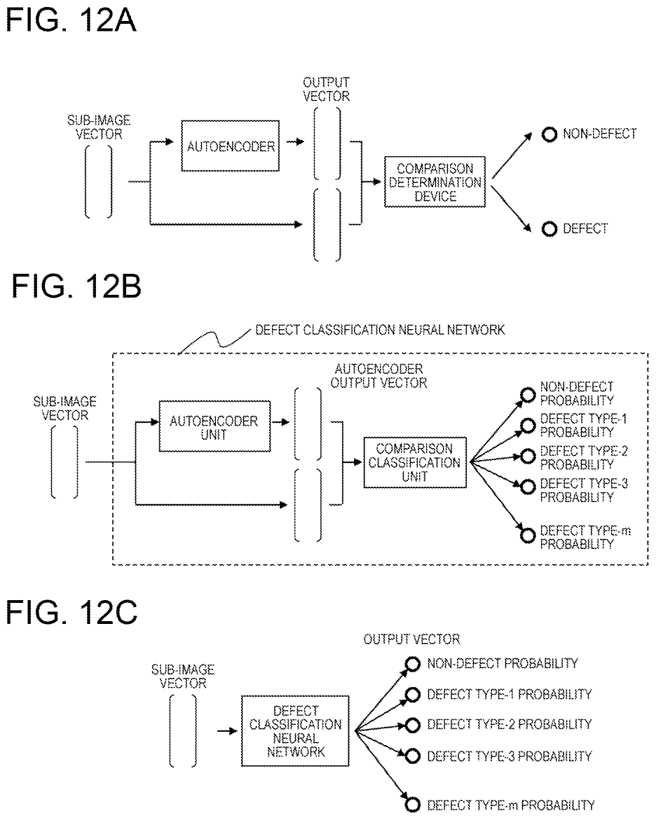

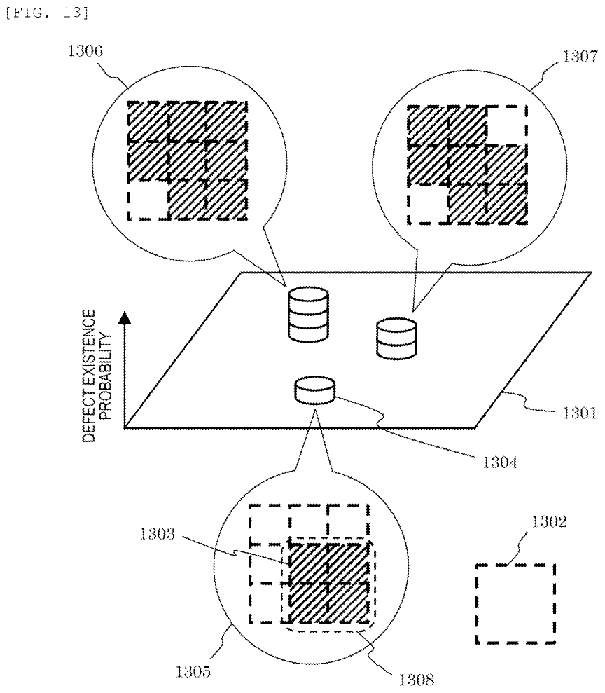

As described in Application Example 1 and the like, inspection using an autoencoder extracts deviations from the normal patterns at a high speed without using the golden images, the design information, or the like. That is, as illustrated in FIG. 12(a), a sub-image clipped from an inspection image is input to the autoencoder, and an output thereof is compared with the input to determine whether the sub-image is defective or non-defective.

However, in order to analyze a cause of defect generation and take countermeasures, it is desirable to acquire information on the type of the extracted defect. Therefore, in this Application Example, in order to classify the types of the extracted defects (bridges of pattern lines, breakage of pattern lines, disappearance of isolated patterns, exceeding the allowable value of LER, local undulations of pattern lines, other pattern dimensional shape fluctuations, various foreign matter defects, and the like), the following two methods are tried.

In the first method, first, the defect concern point is extracted by the autoencoder. Next, the ADC is selectively used to classify and determine the defect in the pattern image in the vicinity of the defect concern point. As the ADC, for example, a combination of an image analysis method and machine training such as a support vector machine (SVM), or various techniques such as supervised machine learning (deep learning using CNN) can be used. By using this method, the types of the various defects described above are determined.

One or more computer systems are provided with a module including an ADC module and the autoencoder, so that the extraction of the portion which can be a candidate for the defect can be performed at a high speed, and the work up to defect the classification can be efficiently performed.

In the second method, without dividing and applying the autoencoder and the ADC in two stages as in the first method, the defect classification and determination are performed by using one defect classification neural network as illustrated in FIG. 12(b). The defect classification neural network illustrated in FIG. 12(b) is configured with an autoencoder unit and a comparison classification unit. A large number of the sub-images are generated from the SEM image of the inspection target as described in Application Examples 1 to 7, and each sub-image is input to the defect classification network of FIG. 12(b). In the network, first, each sub-image is input to the autoencoder unit, and after that, the obtained autoencoder output and the original sub-image are simultaneously input to the comparison classification unit. The comparison classification unit is, for example, a neural network such as a multiperceptron or a CNN that receives the combined vector or matrix of the autoencoder output and the original sub-image as an input, and outputs the probability that the input sub-image is non-defective or various defective.

The training of the defect classification network is performed as follows. First, as described in Application Example 1 to Application Example 7, the autoencoder is trained to reproduce and output the input as much as possible when sub-images generated from the patterns in the normal range are input. Next, a large number of the images including the defects are input to the autoencoder unit to create the labeled training data of the defect images.

Specifically, marking is performed on the non-defective sub-images (output number=0) from which the defects are not extracted and the corresponding defect types of the sub-images (output number=1, 2, . . . ) from which the defects are extracted. The labeled training data may be created by another method without referring to the autoencoder output. Next, a large number of the images containing the defects are input to the entire defect classification network, and the training is performed by using the labeled training data. However, at this time, the network of the autoencoder unit is fixed, and only the network of the comparison classification unit is trained. Even in this method, bridges of pattern lines, breakage of pattern lines, disappearance of isolated patterns, exceeding the allowable value of LER, local undulation of pattern lines, other pattern dimensional shape fluctuations, various foreign matter defects, or the like can be determined.

In the above-described second method, although the autoencoder unit and the comparison classification unit are explicitly divided and trained separately, the training may be performed as one network as illustrated in FIG. 12(c).

### REFERENCE SIGNS LIST

801 electron source

802 extraction electrode

803 electron beam

804 condenser lens

805 scanning deflector

806 objective lens

807 sample chamber

808 sample stage

809 sample

810 electron

811 secondary electron

812 conversion electrode

813 detector

814 controller

815 A/D converter

816 image processing unit

817 CPU

818 image memory

819 storage medium

820 workstation

1. A system configured to detect defects on a semiconductor wafer, wherein the system is provided with one or more computer systems specifying the defects included in a received input image, the one or more computer systems are provided with a training device including an autoencoder trained in advance by inputting a plurality of images at different locations included in a training image, and one or more computer systems divide the input image, input the divided input images to the autoencoder, and compare an output image output from the autoencoder with the input image.

2. The system according to claim 1, wherein the one or more computer systems are configured to divide the input image into a plurality of sub-images and train the autoencoder based on a plurality of divided sub-images.

3. The system according to claim 1, wherein the one or more computer systems are configured to detect the defects included in the image by training the autoencoder based on input of a training input image and inputting a plurality of inspection sub-images to the autoencoder that is trained.

4. The system according to claim 1, wherein a size on the semiconductor wafer corresponding to the plurality of images of the different locations is larger than one time and smaller than four times a minimum dimension of an object included in the plurality of images.

5. The system according to claim 1, wherein the one or more computer systems are configured to divide the input image into the plurality of sub-images while providing an overlapped region.

6. The system according to claim 1, wherein the one or more computer systems are configured to evaluate a degree of discrepancy of the input image and the output image.

7. The system according to claim 6, wherein the one or more computer systems are configured to allow a display device to display a frequency distribution of the degree of discrepancy or a distribution on the semiconductor wafer.

8. The system according to claim 6, wherein the one or more computer systems are configured to divide the input image into the plurality of sub-images while providing an overlapped region, evaluate the degree of discrepancy of the divided input image and the output image, and allow a display device to display identification information corresponding to the number of sub-images with a degree of discrepancy being a predetermined value or more among the sub-images constituting the overlapped region.

9. A non-transitory computer-readable medium storing program instructions executable on a computer system to perform a computer-implemented method of detecting defects on a semiconductor wafer, wherein the computer-implemented method is provided with a training device including an autoencoder trained in advance by inputting a plurality of images at different locations included in a training image, and the one or more computer systems divide the input image, input the divided input image to the autoencoder, and compare an output image output from the autoencoder with the input image.

10. A system for processing image signals obtained based on irradiation of a semiconductor wafer with a beam, wherein the system includes one or more computer systems computing difference information between first image data and second image data, and the one or more computer systems are configured to calculate a frequency for each degree of difference between the first image data and the second image data.

11. The system according to claim 10, wherein the one or more computer systems are configured to generate a histogram indicating the frequency for each degree of discrepancy for each pixel of the first image data and the second image data.

12. The system according to claim 11, wherein the one or more computer systems are configured to evaluate a shape of the histogram.

13. The system according to claim 11, wherein the one or more computer systems are configured to allow a display device to display the different histograms obtained from different semiconductor wafers manufactured at different manufacturing timings.

14. The system according to claim 10, wherein the one or more of computer systems are provided with a training device including an autoencoder trained in advance by inputting a plurality of images at different locations included in a training image, and wherein the one or more computer systems divide the second image, input the divided input image to the autoencoder, and compare a first image output from the autoencoder with the second image.

15. The system according to claim 10, wherein the one or more computer systems are configured to evaluate the degree of discrepancy of the first image and the second image for each pixel.
